(19) United States
(12) Patent Application Publication
(10) Pub. No.: US 2018/0286719 A1
(43) Pub. Date: Oct. 4, 2018

(54) FILM FORMING APPARATUS AND FILM FORMING METHOD

(71) Applicant: NuFlare Technology, Inc., Kanagawa (JP)

(72) Inventors: Yasushi IYECHIKA, Matsudo, Chiba (JP); Takanori HAYANO, Yokohama (JP); Hideshi TAKAHASHI, Yokohama (JP)

(21) Appl. No.: 15/937,275

(22) Filed: Mar. 27, 2018

(30) Foreign Application Priority Data
Mar. 28, 2017 (JP) 2017-063076
Jan. 16, 2018 (JP) 2018-005160

(51) Int. Cl. H01L 21/67; H01L 21/02; H01L 21/66

(52) U.S. Cl. CPC H01L 21/67248; H01L 21/0262; H01L 22/20; H01L 21/67115; H01L 21/0254

(57) ABSTRACT

A film forming apparatus according to the present embodiment includes a film forming chamber accommodating a substrate and performing a film forming process per substrate, a gas supplier supplying a gas onto the substrate, a heater heating the substrate, a window provided to the film forming chamber, a radiation thermometer measuring a temperature of the substrate through the window, a parameter acquirer acquiring a parameter correlated with the temperature of the substrate, a corrector correcting the temperature of the substrate based on a change from an initial value of the parameter, and a controller controlling the heater based on the temperature of the substrate or the temperature of the substrate thus corrected.

### CROSS REFERENCE TO RELATED APPLICATIONS

This application is based upon and claims the benefit of priority from the prior Japanese Patent Applications No. 2017-063076, filed on Mar. 28, 2017 and No. 2018-005160, filed on Jan. 16, 2018, the entire contents of which are incorporated herein by reference.

### FIELD

Embodiments relate to a film forming apparatus and a film forming method.

### BACKGROUND

A film forming apparatus, such as an MOCVD (Metal Organic Chemical Vapor Deposition) apparatus, is industrially very important for forming a thin film on a substrate having a uniform wide area. In such a thin-film forming apparatus, since the thin film quality is largely influenced by the substrate temperature during film formation, it is required to measure and control the substrate temperature during the film formation. Concerning the substrate temperature measurements, among several types of measuring methods, a method using a radiation thermometer is widely used. The radiation thermometer measures a thermal radiation light intensity from a heated measurement target and acquires a temperature of the measurement target from the measured thermal radiation light intensity. The uniqueness of the temperature measurement with the radiation thermometer is such that the temperature measurement is possible without contact with the measurement target and the time required for measurement is very short. Because of its uniqueness, the temperature measurement with the radiation thermometer is used for a thin-film forming apparatus, such as the MOCVD apparatus, for which it is usual to form a film in an atmosphere or a condition largely different from air.

In order to accurately measure the temperature of the measurement target with the radiation thermometer, it is required to measure the thermal radiation light intensity from the measurement target. In general, in order to measure the thermal radiation light intensity from the measurement target in the film forming apparatus, a light transmission window is installed in a wall surface of the film forming apparatus and, through the window, the measurement of the thermal radiation light intensity is performed. For the material of the light transmission window, it is general to use an optically transparent material such as quartz.

However, when a thin-film forming operation is repeated, deposits are gradually adhered to the inner surface of a window member for temperature measurements. The deposit adhesion causes the occurrence of fogging on the window member. When fogging occurs on the window member, the thermal radiation light intensity from a substrate on which a thin film is formed is reduced, so that the radiation thermometer cannot measure an accurate substrate temperature through the window member.

When a measured temperature error of the radiation thermometer becomes large, the film forming apparatus cannot form a thin film of a desired film thickness or film quality. Therefore, whenever fogging occurs on the window member, it is required to open the film forming apparatus, the inside of which is required to be isolated from the atmosphere of air, to perform maintenance of the window member. Such maintenance makes worse the throughput of a film forming process, which leads to reduction in productivity.

### SUMMARY

A film forming apparatus according to the present embodiment includes a film forming chamber accommodating a substrate and performing a film forming process per substrate, a gas supplier supplying a gas onto the substrate, a heater heating the substrate, a window provided to the film forming chamber, a radiation thermometer measuring a temperature of the substrate through the window, a parameter acquirer acquiring a parameter correlated with the temperature of the substrate, a corrector correcting the temperature of the substrate based on a change from an initial value of the parameter, and a controller controlling the heater based on the temperature of the substrate or the temperature of the substrate thus corrected.

The corrector may correct the temperature of the substrate in view of change in emissivity due to temperature or due to an optical interference effect caused by a formed thin film.

The corrector may correct the temperature of the substrate based on a first reflected light intensity acquired as the parameter before a first film forming process and a second reflected light intensity acquired as the parameter before a second film forming process after the first film forming process.

The apparatus may further comprise an environment thermometer measuring an environment temperature of the film forming chamber, wherein the corrector corrects the temperature of the substrate based on the first reflected light intensity and the second reflected light intensity measured in a substantially same environment temperature.

The corrector may correct the temperature of the substrate based on a ratio of the first reflected light intensity and the second reflected light intensity.

The corrector may correct an emissivity based on a ratio of the first reflected light intensity and the second reflected light intensity to calculate a corrected emissivity, and uses a thermal radiation light intensity and the corrected emissivity to calculate the temperature of the substrate.

The corrector may correct the temperature of the substrate based on a growth rate of a predetermined film formed on the substrate, the growth rate being acquired as the parameter.

The corrector may correct the temperature of the substrate based on a refractivity of a predetermined film formed on the substrate, the refractivity being acquired as the parameter.

A film forming method according to the present embodiment is to supply a gas onto a substrate while heating the substrate accommodated in a film forming chamber to a predetermined temperature, measuring a temperature of the substrate through a window provided to the film forming chamber, acquiring a parameter correlated with the temperature of the substrate, correcting the temperature of the substrate based on a change from an initial value of the parameter, and controlling the heater so that the temperature of the substrate thus corrected becomes the predetermined temperature.

The temperature of the substrate may be corrected in view of change in emissivity due to temperature or due to an optical interference effect caused by a formed thin film.

The method may further comprise, in the correction of the temperature of the substrate, correcting the temperature of the substrate based on a first reflected light intensity acquired as the parameter before a first film forming process and a second reflected light intensity acquired as the parameter before a second film forming process after the first film forming process.

The temperature of the substrate may be corrected based on the first reflected light intensity and the second reflected light intensity measured in a substantially same environment temperature.

The temperature of the substrate may be corrected based on a ratio of the first reflected light intensity and the second reflected light intensity.

The method may further comprise, in the correction of the temperature of the substrate: correcting an emissivity based on the ratio of the first reflected light intensity and the second reflected light intensity to calculate a corrected emissivity and; calculate the temperature of the substrate using a thermal radiation light intensity and the corrected emissivity.

The method may further comprises, in the correction of the temperature of the substrate, correcting the temperature of the substrate based on a growth rate of a predetermined film formed on the substrate, the growth rate being acquired as the parameter.

The method may further comprises, in the correction of the temperature of the substrate, correcting the temperature of the substrate based on a refractivity of a predetermined film formed on the substrate, the refractivity being acquired as the parameter.

### BRIEF DESCRIPTION OF THE DRAWINGS

FIG. 1 is a figure schematically showing a configuration of a film forming apparatus according to a first embodiment;

FIG. 2 is a schematic view showing that a radiation thermometer and an optical monitor measure a thermal radiation light intensity and a reflected light intensity, respectively, through a light transmission window;

FIG. 3 is a figure showing measured values of an early-stage reflected light intensity ratio of a wafer to the number of times of film forming process;

FIG. 4 is a flowchart showing an example of the operation of the film forming apparatus according to the first embodiment:

FIG. 5 is a figure showing measured values of a half width of diffraction intensity peak on an AIN (102) plane with the X-ray rocking curve;

FIG. 6 is a figure showing measured values of reflectivity varied with time during AlN- and AlGaN-film formation;

FIG. 7 is a figure showing measured values of a GaN growth rate ratio;

FIG. 8 is a flowchart showing an operation of a film forming apparatus according to a second embodiment; and

FIG. 9 is a figure showing an example of measuring points of chamber environment temperatures.

### DETAILED DESCRIPTION

Embodiments will now be explained with reference to the accompanying drawings.

### First Embodiment

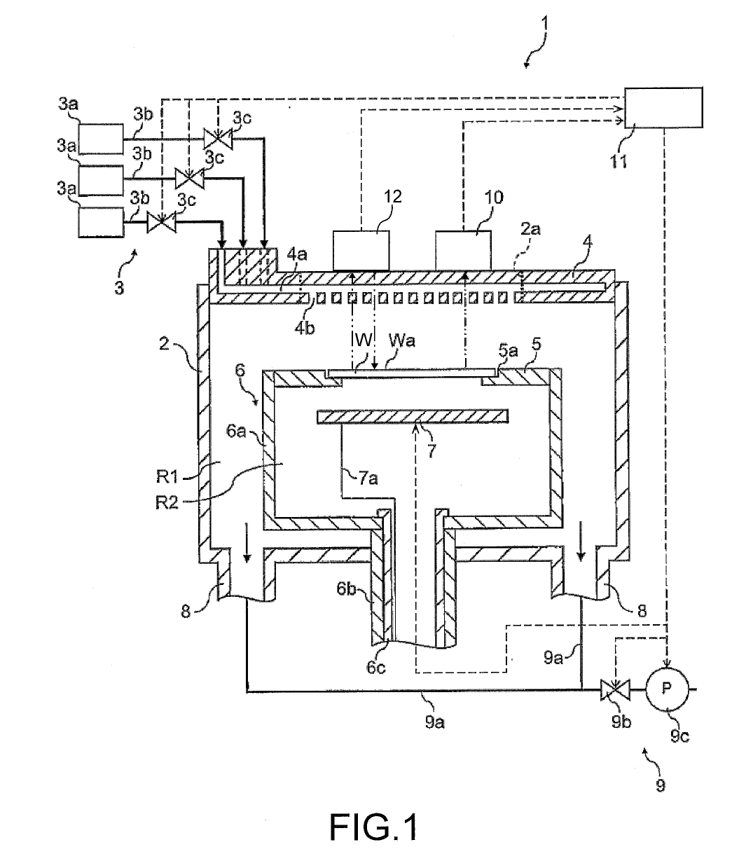

FIG. 1 is a figure schematically showing a configuration of a film forming apparatus 1 according to a first embodiment. In the present embodiment, an example will be explained in which, as a substrate to be subjected to film formation, a silicon substrate, specifically, a silicon wafer (merely referred to as a wafer, hereinafter) W is used, and a single film or a plurality of thin films are laminated on the wafer W in film formation. Hereinafter, an explanation will be made with MOCVD as an example of a vapor deposition method.

The film forming apparatus 1 of FIG. 1 is provided with a chamber 2 for film formation on the wafer W, a gas supplier 3 for supplying a source gas to the wafer W in the chamber 2, a source discharger 4 located above the chamber 2, a susceptor 5 for holding the wafer W in the chamber 2, a rotating part 6 that rotates while holding the susceptor 5, a heater 7 for heating the wafer W, a gas exhauster 8 for exhausting a gas in the chamber 2, an exhaust mechanism 9 for exhausting a gas from the gas exhauster 8, a radiation thermometer 10 for measuring a temperature of the wafer W, a controller 11 for controlling the component parts, and an optical monitor 12 for measuring a reflected light intensity from the wafer W.

The chamber 2, as a film forming chamber, has a shape (such as a cylindrical shape) capable of accommodating the wafer W to be subjected to film formation. The chamber 2 accommodates the susceptor 5, the heater 7, part of the rotating part 6, etc.

The gas supplier 3 has a plurality of gas storages 3a for respectively storing a plurality of gases, a plurality of gas pipes 3b for connecting the gas storages 3a and the source discharger 4, and a plurality of gas valves 3c for adjusting flow rates of gases that flow through the gas pipes 3b. Each gas valve 3c is connected to the associated gas pipe 3b. The gas valves 3c are controlled by the controller 11. There are a plurality of configurations for actual piping, such as, coupling a plurality of gas pipes, making one gas pipe to branch to a plurality of gas pipes, and a combination of gas-pipe branching and coupling.

Source gases supplied from the gas supplier 3 pass through the source discharger 4 and are discharged into the chamber 2. The source gases (process gases) discharged into the chamber 2 are supplied onto the wafer W, and, accordingly, a desired film is formed on the wafer W. There is no particular limitation on the types of source gases to be used.

A shower plate 4a is provided on the bottom side of the source discharger 4. The shower plate 4a can be configured with a metal material such as stainless steel and an aluminum alloy. Gases from the gas pipes 3b are mixed one another in the source discharger 4 and pass through gas jetting ports 4b of the shower plate 4a, and then are supplied into the chamber 2. A plurality of gas passages may be provided to the shower plate 4a so as to supply a plurality of types of gases, as being separated from one another, to the wafer W in the chamber 2.

The structure of the source discharger 4 should be selected in view of uniformity of a formed film, material efficiency, reproducibility, production cost, etc. However, there is no particular limitation on the structure, as long as the selected one meets those requirements. Known structures can also be used as required.

The susceptor 5 is provided on the rotating part 6 to hold the wafer W in such a manner that the wafer W is placed in a counterbore provided in the inner peripheral side of the susceptor 5. In the example of FIG. 1, the susceptor 5 is formed into an annular shape with an opening at its center, however, may be formed into a roughly flat shape without the opening.

The heater 7 is a heating part for heating the susceptor 5 and/or the wafer W, with no particular limitation as long as meeting the requirements of the capability of heating a heating target at a desired temperature and in desired temperature distribution, durability, etc. As examples, specifically, resistance heating, lamp heating, induction heating, etc. are listed up.

The exhaust mechanism 9 exhausts a reacted source gas from the inside of the chamber 2 via the gas exhauster 8 and controls the pressure inside the chamber 2 to a desired pressure with the operations of an exhaust valve 9b and a vacuum pump 9c.

The radiation thermometer 10 is provided on the upper surface of the source discharger 4. The radiation thermometer 10 measures the temperature of the wafer W. The wavelength range of thermal radiation light to be measured by the radiation thermometer 10 is from a visible light wavelength to a near infrared light wavelength. In the case where the wafer W is made of sapphire, silicon carbide (SiC), etc., transparent (hereinafter, referred to as a transparent substrate) in the above-described wavelength range, a radiation thermometer cannot directly measure the temperature of the wafer W, and hence it is general to measure the temperature of the susceptor 5 using the intensity of thermal radiation light from the susceptor 5, which has passed through the transparent substrate. The temperature of the wafer W can be monitored with the temperature of the susceptor 5 measured in the above-described way. It is a precondition in the present embodiment that the substrate is the wafer W that is opaque in the wavelength range to be measured by the radiation thermometer. Nevertheless, even when the water W is a transparent substrate, a method of correcting the influence of fogging on a light transmission window, which will be described in detail hereinbelow, can also be performed for the temperature of the susceptor 5.

The radiation thermometer 10 receives thermal radiation light from the wafer W to measure a thermal radiation light intensity. The radiation thermometer 10 uses the thermal radiation light intensity to calculate the temperature of the wafer W. The radiation thermometer 10 has a built-in data arithmetic unit that acquires the temperature of the wafer W from the thermal radiation light intensity. The data arithmetic unit can be configured, for example, with a general purpose computer. The temperature of the wafer W measured by the radiation thermometer 10 is fed back to the controller 11 for use in controlling an actual temperature of the wafer W to a predetermined temperature.

A light transmission window 2a is provided on the upper surface of the source discharger 4. Light from a light source of the optical monitor 12, and reflected light and thermal radiation light each from the wafer W pass through the light transmission window 2a. The light transmission window 2a may be formed into any shape such as a slit shape, a rectangular shape, and a circular shape. A member used for the window is transparent in a wavelength range of light to be measured by the radiation thermometer 10. In the case of measuring the temperature from a room temperature to about 1500° C., it is preferable to measure a wavelength of light in the range from a visible range to a near infrared range. In this case, as a window member, quartz glass is preferably used.

The controller 11 is provided with a computer for centralized control of component parts of the film forming apparatus 1 and a storage unit for storing film formation information related to film formation, a several types of programs, etc. Based on the film formation information, the several types of programs, etc., the controller 11 controls the gas supplier 3, the rotation mechanism of the rotating part 6, the exhaust mechanism 9, etc. to control the heating of the wafer W by the heater 7 and the like. For example, the controller 11 controls the heater 7 so that a temperature of the wafer W measured by the radiation thermometer 10 becomes a predetermined temperature.

When the wafer W is heated to a high temperature, the chamber 2, the source discharger 4, the gas exhauster 8, etc. may be cooled down. When the source discharger 4, and the like, provided on the upstream side of the wafer W are heated to a high temperature more than needed, a gas phase reaction such as source-material predecomposition occurs on the portion where is heated to the high temperature more than needed, which is not preferable in film formation on the wafer W. Moreover, impurities are discharged into a source gas from the portion where is heated to the high temperature more than needed, which results in a lot of impurities contained in a film formed on the wafer W. In order to avoid the occurrence of the above-described unpreferable gas phase reaction, it is preferable to keep the temperature on the upstream side of the wafer W at a room temperature or more but 250° C. or less, more preferably, at 60° C. or more but 200° C. or less.

When a portion of the chamber 2 that isolates air and a reaction chamber is heated to a high temperature more than needed, there is a risk of burning when a human body touches the above-described portion. In order to avoid such a risk, it is preferable to keep the temperature of a portion exposed to air at 100° C. or less.

As a method for controlling the temperature described above, it is general to provide a flow channel at the section where temperature control is required, to feed a coolant therethrough. The coolant may be water, a solvent of water and a liquid soluble in water, a liquid of an organic or inorganic material, and so on. It is effective for film formation with excellent repeatability to perform temperature control with the coolant flowing through the flow channel at a constant temperature.

The optical monitor 12 is provided on the upper surface of the source discharger 4, in the same manner as the radiation thermometer 10. The optical monitor 12 may be provided apart from the radiation thermometer 10, however, is preferably provided near the radiation thermometer 10.

Moreover, in the film forming apparatus 1 shown in FIG. 1, it is more preferable that the optical monitor 12 and the radiation thermometer 10 are arranged on opposite sides of a rotation axis of the wafer W with a roughly same distance from the rotation axis. When fogging occurs non-uniformly on the light transmission window 2a, since the film forming apparatus shown in FIG. 1 is roughly rotational symmetric about the rotation axis of the wafer W, fogging occurs on the light transmission window 2a, almost symmetrically about the rotation axis of the wafer W. Therefore, the optical monitor 12 and the radiation thermometer 10 can be arranged at the positions of almost the same degree of fogging by arranging the optical monitor 12 and the radiation thermometer 10 in such a manner described above. Accordingly, the influence of fogging non-uniformity on the light transmission window 2a can be reduced. Even in the case where a plurality of radiation thermometers 10 and a plurality of optical monitors 12 are installed, the influence of fogging non-uniformity on the light transmission window 2a can be reduced and each radiation thermometer 10 can show the effect of the present embodiment, by arranging the optical monitors 12 and the radiation thermometers 10 almost symmetrically about the rotation axis of the wafer W.

More preferably, it is considered to match an optical axis along which thermal radiation light passes from the wafer W to the radiation thermometer 10 and an optical axis of the optical monitor 12 with each other. Having the optical axes of the optical monitor 12 and the radiation thermometer 10 matched with each other, the optical monitor 12 can directly evaluate the area of the light transmission window 2a that influences the measurement of thermal radiation light intensity by the radiation thermometer 10. The arrangement described above can be favorably carried out even when the fogging non-uniformity on the light transmission window 2a is not symmetrical. The optical-axis matching between the optical monitor 12 and the radiation thermometer 10 can be done with an appropriate combination of optical components such as the light source and a half mirror of the optical monitor 12.

The radiation thermometer 10 may be provided on the susceptor 5 when a transparent substrate is used.

The optical monitor 12, as a parameter acquirer, emits light to the wafer W through the light transmission window 2a, to measure a reflected light intensity, as a parameter, from the wafer W through the light transmission window 2a. The optical monitor 12 is installed, for example, above the center area and/or the outer peripheral area of the wafer W or a thin film, to measure a reflected light intensity from the corresponding part of the wafer W. The reflected light intensity is used for correcting a measured temperature value of the wafer W calculated by the radiation thermometer 10. The correction of the measured temperature value of the wafer W will be explained later.

When the film forming apparatus 1 repeatedly performs film formation, deposits are produced to cause the occurrence of fogging on the light transmission window 2a, which reduces a transmittance Tr of the light transmission window 2a.

Reduction in the transmittance Tr causes reduction in the reflected light intensity measured by the optical monitor 12 and the thermal radiation light intensity measured by the radiation thermometer 10. For example, the transmittance Tr of the light transmission window 2a before fogging occurs is 1, however, reduces to a value smaller than 1 and then reaches near zero. In other words, the transmittance Tr of the light transmission window 2a is changeable in the range from 1 to 0 (0≤Tr≤1) depending on the deposits adhered to the light transmission window 2a.

The transmittance of the light transmission window 2a is influenced by reflection on the surface of a window member, light absorbance or scattering by the window member, etc. Nevertheless, in the following discussion, ignoring those influences, the transmittance is defined to 1 in the state where no fogging occurs on the light transmission window 2a. The definition of transmittance causes no problems on the effectiveness of the present embodiment, because, in the present embodiment, the influence of fogging on the light transmission window 2a is expressed with a comparison between the state where fogging occurs and the state where no fogging occurs. In order to remove the influence of an actual transmittance of the light transmission window 2a with no occurrence of fogging, it is required to correct the radiation thermometer 10 in advance using a temperature measuring method that is not influenced by the transmittance of the light transmission window 2a. Listed up as temperature measuring methods without being influenced by the transmittance of the light transmission window 2a are methods of melting a material whose melting point is already known, using a two-color radiation thermometer, measuring a thermal radiation spectrum with fitting using the black body radiation formula, etc. Among the listed methods, the methods of using the two-color radiation thermometer and measuring the thermal emission spectrum are methods of acquiring a target temperature from thermal-radiation light intensity wavelength distribution, theoretically, receiving no influences of the transmittance of the light transmission window 2a. It is, however, known that a thin film grown on a substrate has a large reflectivity wavelength distribution due to an optical interference effect. Therefore, the methods of using the two-color radiation thermometer and, measuring and analyzing the thermal radiation spectrum have a difficulty in temperature measurement during thin film formation. Accordingly, the temperature measurement during thin film formation requires a monochrome radiation thermometer having a narrowly-restricted measurement wavelength.

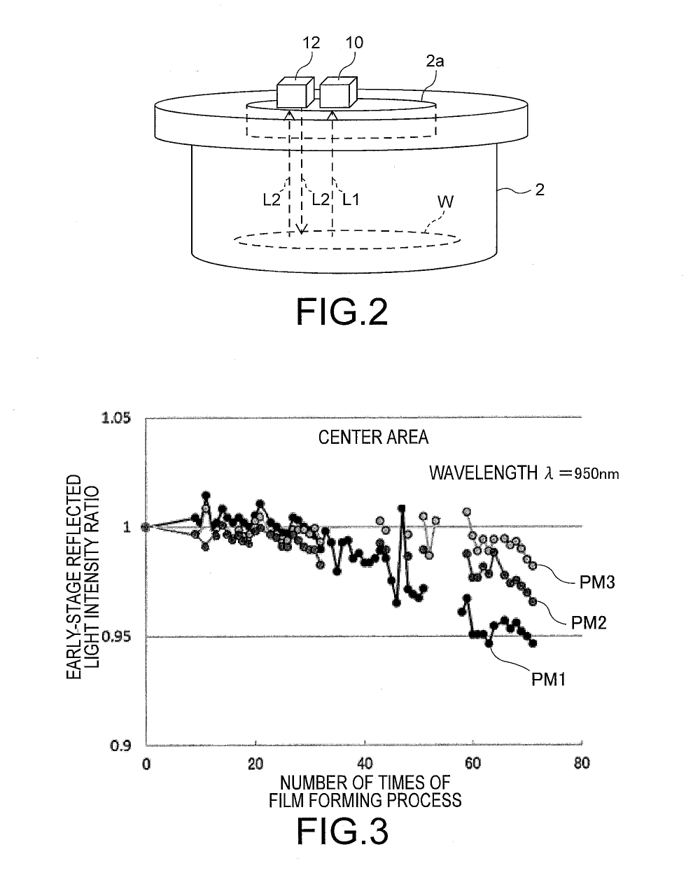

Referring to FIG. 2, a temperature error of the wafer W will be explained more in detail.

FIG. 2 is a schematic view showing that the radiation thermometer 10 and the optical monitor 12 measure the thermal radiation light intensity and the reflected light intensity, respectively, through the light transmission window 2a. Although FIG. 2 shows one radiation thermometer 10 and one optical monitor 12, a plurality of radiation thermometers 10 and a plurality of optical monitors 12 may be provided so as to be associated with the center area, outer peripheral area, etc. of the wafer W.

When the radiation thermometer 10 measures the temperature of the wafer W, thermal radiation light L1 once passes through the light transmission window 2a. When deposits are adhered to the light transmission window 2a due to a film forming operation of the film forming apparatus 1, the transmittance Tr of the light transmission window 2a becomes smaller than 1. In this case, whenever passing through the light transmission window 2a, the light L1 becomes Tr times, and hence the thermal radiation light intensity measured by the radiation thermometer 10 reduces to Tr times, compared with the case where no fogging occurs on the light transmission window 2a (Tr=1). In this case, the radiation thermometer 10 cannot measure an accurate temperature of the wafer W. The measured temperature of the radiation thermometer 10 is fed back to the controller 11 for use in control of an actual temperature of the wafer W. Therefore, the error of the measured temperature becomes a cause of error in the actual temperature of the wafer W.

For the above reasons, according to the present embodiment, the optical monitor 12, as a parameter acquirer, measures a first early-stage reflected light intensity before an initial film forming process, as a first film forming process, and then measures a second early-stage reflected light intensity before a second film forming process after the initial film forming process. The optical monitor 12 calculates a ratio of the first early-stage reflected light intensity and the second early-stage reflected light intensity, as an early-stage reflected light intensity ratio of the wafer W, and acquires the transmittance Tr of the light transmission window 2a from an early-stage reflected light intensity that is reduced due to fogging on the light transmission window 2a. The film forming apparatus 1 uses the transmittance Tr to correct an emissivity or a measured temperature. The early-stage reflected light intensity is, in a film forming process of each wafer W, a reflected light intensity of the wafer W measured by the optical monitor 12 before the film forming process. In other words, the early-stage reflected light intensity of the wafer W is a reflected light intensity measured through the light transmission window 2a before the film forming process of the wafer W, after the wafer W is transferred into the chamber 2 in each film forming process.

FIG. 3 is a figure showing measured values of the early-stage reflected light intensity ratio of the wafer W to the number of times of film forming process. The abscissa indicates the number of times of film forming process and the ordinate indicates the early-stage reflected light intensity ratio. The data of FIG. 3 are acquired from three chambers 2 installed in one film forming apparatus and operating in parallel. In FIG. 3, PM1 to PM3 denote the three chambers 2 of the forming apparatus.

The early-stage reflected light intensity ratio is a ratio (Ir2/Ir1) of an early-stage reflected light intensity (first early-stage reflected light intensity) Ir1 measured before a given film forming process (first film forming process) and an early-stage reflected light intensity (second early-stage reflected light intensity) Ir2 measured before a second film forming process after the first film forming process. It is defined that, when the number of times of film forming process is 0, the early-stage reflected light intensity ratio is a ratio (Ir1/Ir1=1) of the first early-stage reflected light intensity Ir1 and the first early-stage reflected light intensity Ir1.

The first early-stage reflected light intensity Ir1 is an early-stage reflected light intensity measured, before a first-time film forming process, for example, through a new (just replaced) light transmission window. 2a. In other words, the first early-stage reflected light intensity Ir1 is an early-stage reflected light intensity measured before the first-time film forming process of the wafer W after the light transmission window 2a is replaced with a new one. The second early-stage reflected light intensity Ir2 is an early-stage reflected light intensity measured before the execution of a film forming process that is a second-time film forming process or any film forming process after the second-time film forming process. In other words, the second early-stage reflected light intensity Ir2 is an early-stage reflected light intensity measured before the second-time film forming process or any film forming process after the second-time film forming process of the wafer W after the light transmission window 2a is replaced with a new one. The first early-stage reflected light intensity Ir1 may be measured after the execution of film forming process several times if there is no fogging on the light transmission window 2a. In this case, the second early-stage reflected light intensity Ir2 is a reflected light intensity measured before any film forming process after measurement of the first early-stage reflected light intensity Ir1.

As described above, when the number of times of film forming process is 0, the early-stage reflected light intensity ratio is the ratio (Ir1/Ir1=1) of the first early-stage reflected light intensity Ir1 and the first early-stage reflected light intensity Ir1. When the number of times of film forming process is 1 or larger, the early-stage reflected light intensity ratio (Ir2/Ir1) has a tendency to reduce as the number of times of film forming process increases.

As described above, since the transmittance Tr of the light transmission window 2a is correlated with the early-stage reflected light intensity ratio, the radiation thermometer 10 or the optical monitor 12 according to the present embodiment can calculate the transmittance Tr based on the early-stage reflected light intensity ratio. The radiation thermometer 10 or the controller 11 uses the transmittance Tr to correct the emissivity or the measured temperature.

Hereinafter, the calculation of the transmittance Tr and the correction of the emissivity or the measured temperature will be explained in detail.

(Calculation of Transmittance Tr of Light Transmission Window 2a)

FIG. 2 is referred to again. When the optical monitor 12 measures the reflected light intensity, after light L2 from the optical monitor 12 passes through the light transmission window 2a having the transmittance Tr, the light L2 is reflected by the wafer W and then passes through the light transmission window 2a again to return to the optical monitor 12. Therefore, in order for the optical monitor 12 to measure the reflected light intensity, the light L2 reciprocates between the optical monitor 12 and the wafer W to pass through the light transmission window 2a two times. As described above, since light becomes Tr times whenever the light passes through the light transmission window 2a one time, the intensity (reflected light intensity) of the light L2 measured by the optical monitor 12 becomes (Tr)² times compared with the case where there is no fogging on the light transmission window 2a. When the film forming apparatus 1 performs a film forming operation, if the transmittance Tr of the light transmission window 2a becomes smaller than 1, the reflected light intensity measured by the optical monitor 12 reduces to (Tr)² times in accordance with the reduction in the transmittance Tr smaller than 1, unless the reflected light intensity and radiated light intensity measured by the optical monitor 12 do not vary.

In general, a reflectivity R and an emissivity E of a substance have the relationship of an expression 1 where it is assumed that the transmittance of this substance is 0 (opaque).

ε+R=1 (expression 1)

The emissivity ε of the wafer W during film formation can be acquired from the reflectivity R using the expression 1. Although the emissivity E may vary largely in the formation of a thin film on the wafer W, since the emissivity E during the film formation can be evaluated by measuring the reflectivity R with the expression 1, an accurate temperature measurement is possible during film formation. Moreover, in general, the reflectivity of a material is predetermined as a value unique to the material. For example, in the case of silicon, the reflectivity R in the vertical direction to a wafer is about 0.3 in a room temperature to light of about 1 μm in wavelength. Accordingly, before the start of growth, a reflected light intensity is measured by using a material for the wafer W, the reflectivity of the material being already known, and then the relationship between the reflected light intensity and reflectivity can be calibrated from the known reflectivity.

Having the above calibrated relationship, the film forming apparatus 1 can acquire a transmittance Tr of the light transmission window 2a from a measured value of the early-stage reflected light intensity of the wafer W. For example, if there is fogging on the light transmission window 2a, its transmittance Tr becomes smaller than 1, and accordingly, the early-stage reflected light intensity measured by the optical monitor 12 reduces to (Tr)² times. The optical monitor 12 can calculate the transmittance Tr of the light transmission window 2a by calculating (a reduction rate of the early-stage reflected light intensity)^{1/2}.

In the present embodiment, it is assumed that the transmittance of a new light transmission window 2a just replaced is 1, with the first early-stage reflected light intensity Ir1 as a denominator. Therefore, when an early-stage reflected light intensity measured before a second growth process is Ir1, the transmittance Tr is calculated as (Ir2/Ir1)^{1/2}.

Several points to notice are listed up hereinbelow. First of all, it may not always be necessary to measure the early-stage reflected light intensity of each wafer to be subjected to the film forming process in acquiring the above-mentioned transmittance Tr. In other words, the transmittance Tr of the light transmission window 2a may be periodically acquired using wafers for measurement (standard sample wafers) of identical materials having the same optical characteristics and quality. Nevertheless, in the case of frequent film formation using the same type of wafers, it is preferable to periodically perform transmittance measurements using wafers to be subjected to the film forming process. This is because there is no necessity of replacements between the standard sample wafers and the wafers to be subjected to the film forming process, with no productivity losses.

Even for identical materials, their reflectivities may be different. For example, the reflectivity of a material depends on temperature in general. Furthermore, when the material is crystalline, the reflectivity may depend on plane orientation, polarization direction, etc. In measurements of the early-stage reflected light intensity for transmittance measurements, the factor that affects the above-mentioned reflectivity is required to be the same.

It is required to take out a film-formed wafer W of the chamber 2 at an early stage of temperature falling in order to raise productivity with excellent film formation. Therefore, when a new wafer W is transferred into the chamber 2, the temperature inside the chamber 2 dose not reduce enough, so that the temperature of the wafer W newly transferred into the chamber 2 reduces over time. The early-stage reflected light intensity measured in this condition is unstable, and hence it is required to exercise extreme caution in early-stage reflected light intensity measurements.

One specific method for measuring the early-stage reflected light intensity at high accuracy is to measure an environment temperature inside the chamber 2 and control the temperature inside the chamber 2 to be constant for each measurement of the early-stage reflected light intensity. Another specific method for measuring the early-stage reflected light intensity at high accuracy is to perform the same process from the completion of a film forming process to just before the early-stage reflected light intensity measurement to be performed before the succeeding film formation.

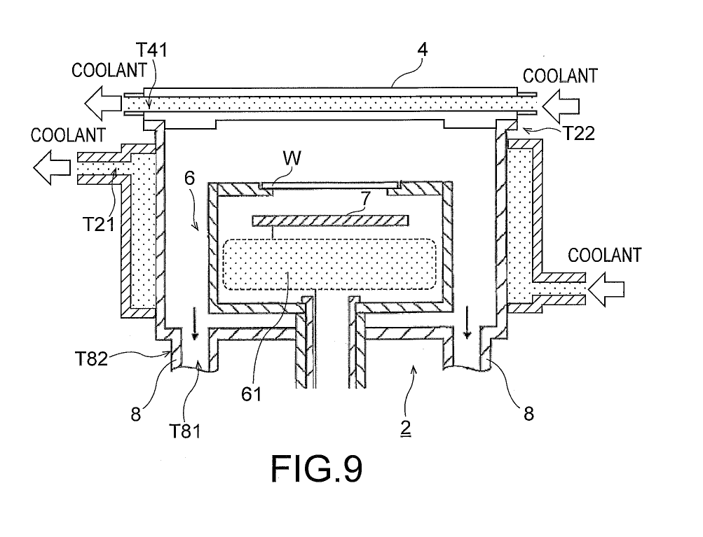

FIG. 9 is a figure showing an example of measuring points of the environment temperature of the chamber 2. The environment temperature of the chamber 2 may be a temperature (T21 and T41) on the outlet side of a cooling water that cools the chamber 2 or the source discharger 4, a temperature T81 of an exhausted gas inside the gas exhauster 8, a temperature (T22 and T82) of the wall surface of the gas exhauster 8, and so on. The temperature of the wall surface is the temperature on the exposed-to-air wall surface of or the inner wall surface of the film forming apparatus 1. Moreover, the environment temperature may be a gas temperature of a lower section 61 inside the chamber 2. The lower section 61 inside the chamber 2 is located inside the rotating part 6 under the heater 7. The larger the distance between the lower section 61 inside the chamber 2 and the heater 7, the larger the difference between the gas temperature of the lower section 61 and the temperature of the wafer W, and hence the relationship between the gas temperature and the temperature of the wafer W becomes unclear. The difference between the gas temperature and the temperature of the wafer W depends on a gas flow rate inside the rotating part 6 or depends on the heater 7 and its peripheral structure. However, as far as the direct distance from the heater 7 to the measuring points is about 30 cm, the correlation between the gas temperature of the lower section 61 inside the chamber 2 and the temperature of the wafer W becomes clear, and hence the gas temperature can preferably be used as the environment temperature of the chamber 2 in the present embodiment. The environment temperature can be easily measured by a thermocouple, a resistance thermometer, and so on.

As for the same process described above, it is important that the film forming process, just before transferring a new wafer W into the chamber 2, completes in the same regular condition every time. The condition at the completion of the film formatting process may be the temperature of the wafer W, the gas type, the gas flow rate, the gas pressure, the rotation speed of the wafer W, the power to be applied to the heater 7, etc. When the listed conditions are unchanged at the completion of the film forming process every time, it is also considered to make constant the periods of transferring the wafer W into and out of the chamber 2 and also make constant the period from the moment of transferring the wafer W into the chamber 2 to the moment of early-stage reflected light intensity measurement. When the condition at the completion of the film forming process is irregular, the early-stage reflected light intensity of a newly transferred wafer W may not be measured accurately. In this case, the new wafer W may be transferred into the chamber 2, followed by the early-stage reflected light intensity measurement, after a dummy run is completed in the above-described regular condition at the completion of the film forming process, the dummy run being performed after a film forming process is completed in an irregular condition at the completion of the film forming process.

It is further required that a light source for measuring the early-stage reflected light intensity is stable over a long period of time. If a radiated light intensity of the above-mentioned light source is not stable in a wavelength range for the early-stage reflected light intensity measurements, the reflected light intensity cannot be acquired correctly and hence the transmittance of a window member of the light transmission window 2a cannot be acquired correctly. Therefore, it is required for the above-mentioned light source, for example, to achieve an emission intensity stable over a long period of time by feed-backing the emission intensity to a driver circuit of the light source. Or the emission intensity may be output to the optical monitor 12 to correct the reflected light intensity. Moreover, in the case where a semiconductor light emitting device such as a light emitting diode is used as a light source, a stable emission intensity is achieved by driving the light emitting device with a driving power source capable of supplying a stable drive current. In the case of driving the light emitting device with a constant current, it should be considered to stabilize the temperature of the light emitting device itself, to set a stabilization time for an enough emission intensity after the start of driving the light emitting device, etc.

Furthermore, it is preferable that the wavelength of reflected light measured by the optical monitor 12 and the wavelength of a thermal radiation light intensity measured by the radiation thermometer 10 are as close as to each other. This is because the light transmission window 2a may show different transmittances depending on wavelength due to fogging. Such a problem can be solved by making close to each other the wavelength of light measured by the optical monitor 12 and the wavelength of thermal radiation light measured by the radiation thermometer 10.

(Correction of Measured Temperature of Wafer W)

When the temperature is denoted as T(K) and the intensity of thermal radiation light having a wavelength λ (μm) emitted from a substance having an emissivity ε is denoted as L, the thermal radiation light intensity L is expressed by the Planck equation shown in an expression 2.

$$L = \frac{2 {c}_{1}}{{λ}^{5}} \frac{ɛ}{exp ( \frac{{C}_{2}}{λ T} ) - 1} \qquad ( expression 2 )$$

where c₁ and c₂ are constants. The constant c₂ is about 14388 K·μm.

As an example, a temperature T of the wafer W in film formation is in the range from about 1000° C. to about 1500° C. The measured wavelength A of thermal radiation light is, for example, 1 μm. In this case, since the first term of the denominator is large enough, “−1” in the second term of the denominator in the right side of the expression 2 may be ignored. In other words, the radiation thermometer 10 may acquire the temperature T of the wafer W using an expression 3. The radiation thermometer 10 can calculate the temperature T of the wafer W by the expression 3 with values of the emissivity ε, thermal radiation light intensity (observed value) L, and wavelength λ.

$$L = \frac{2 {c}_{1}}{{λ}^{5}} \frac{ɛ}{exp ( \frac{{C}_{2}}{λ T} )} \qquad ( expression 3 )$$

In the case where the transmittance Tr of the light transmission window 2a is 1 due to no fogging on the light transmission window 2a, the temperature T calculated by the radiation thermometer 10 is an almost accurate temperature of the wafer W. In contrast, in the case where the transmittance Tr of the light transmission window 2a is smaller than 1 due to fogging on the light transmission window 2a, since the thermal radiation light intensity L is reduced, the temperature T calculated by the radiation thermometer 10 is lower than an actual wafer temperature, which is a temperature including an error (hereinafter, an apparent temperature).

When an actual temperature of the wafer W (hereinafter, a real temperature) is denoted as Ta, in order to calculate the real temperature Ta from a measured value L of the thermal radiation intensity, it is required to correct a preset emissivity E to a corrected emissivity ε_{c}. This makes it possible to calculate the real temperature Ta using the measured value L of the thermal radiation intensity and the corrected emissivity ε_{c}. In order for that, there is a method to acquire the corrected emissivity ε_{c} from the transmittance Tr of the light transmission window 2a to calculate the real temperature Ta using the corrected emissivity ε_{c} (method 1). There is another method to directly calculate the real temperature Ta from the transmittance Tr (method 2).

In the method 1, it is utilized that ε_{c}/ε is equal to the transmittance Tr of the light transmission window 2a. The radiation thermometer 10 corrects E in the expression 3 to ε_{c} (that is ε×Tr) and substitutes ε×Tr for ε in the expression 3. The temperature T calculated in this way is the real temperature Ta. Accordingly, an expression 4 is acquired.

$$L = \frac{2 {c}_{1}}{{λ}^{5}} \frac{{ɛ}_{c}}{exp ( \frac{{C}_{2}}{λ \cdot Ta} )} \qquad ( expression 4 )$$

After the correction of emissivity ε, the radiation thermometer 10 calculates the expression 4 using the measured value L of the thermal radiation intensity.

In this way, the radiation thermometer 10 can acquire the real temperature Ta of the wafer W. In other words, in the method 1, the radiation thermometer 10 corrects the emissivity E to the corrected emissivity ε_{c} and, in a general manner, acquires the temperature of the wafer W from the measured value L of the thermal radiation intensity. In this way, the radiation thermometer 10 can acquire the real temperature Ta of the wafer W. In this case, since the radiation thermometer 10 outputs the real temperature Ta of the wafer W as a measured temperature, the controller 11 controls the heater 7 based on the measured temperature from the radiation thermometer 10.

In the method 2, it is utilized that the thermal radiation intensity L acquired by substituting the corrected emissivity ε_{c} and the real temperature Ta into the expression 3 is equal to the thermal radiation intensity L acquired by substituting the original emissivity ε_{c} and the apparent temperature T into the expression 3. In other words, it is utilized that an expression 5 holds.

$$\frac{2 {c}_{1}}{{λ}^{5}} \frac{ɛ}{exp ( \frac{{C}_{2}}{λ Ta} )} = \frac{2 {c}_{1}}{{λ}^{5}} \frac{{ɛ}_{c}}{exp ( \frac{{C}_{2}}{λ \cdot Ta} )} \qquad ( expression 5 )$$

When the expression 5 is solved, an expression 6 is given.

$$\frac{1}{Ta} = \frac{1}{T} + \frac{λ}{{C}_{2}} log ( \frac{{ɛ}_{c}}{ɛ} ) \qquad ( expression 6 )$$

Since ε_{c}/ε is equal to the transmittance Tr of the light transmission window 2a, the expression 6 is expressed in an expression 7.

$$\frac{1}{Ta} = \frac{1}{T} + \frac{λ}{{C}_{2}} log ( Tr ) \qquad ( expression 7 )$$

The radiation thermometer 10 can calculate the real temperature Ta, using the expression 7, from the temperature Tr of the light transmission window 2a and the measured value L of the thermal radiation intensity acquired through the light transmission window 2a. In this case, the radiation thermometer 10 may calculate the expression 7 to output the real temperature Ta of the wafer W. However, the radiation thermometer 10 may output the apparent temperature T of the wafer W and then the controller 11 may calculate the expression 7 to acquire the real temperature Ta of the wafer W.

The film forming apparatus 1 can control the heater 7 based on an accurate temperature of the wafer W using either of the methods 1 and 2.

For example, in the case where the transmittance Tr of the light transmission window 2a is 95%, the wavelength A of the thermal radiation light is 0.95 μm, and the apparent temperature T is 1273K (1000° C.), the real temperature Ta of the wafer W is 1278K (1005° C.). Such a difference between the apparent temperature T and the real temperature Ta is caused by the determination that the temperature of the wafer W is lower than a predetermined temperature (1000° C.) by 5° C. due to decrease in the transmittance Tr of the light transmission window 2a.

If the radiation thermometer 10 outputs the apparent temperature T and then the controller 11 uses the apparent temperature T to control the heater 7, the controller 11 controls the heater 7 so that the temperature of the wafer W becomes 1005° C. with respect to the set temperature 1000° C.

In contrast, according to the present embodiment, the radiation thermometer 10 outputs a real temperature Ta calculated using the corrected emissivity ε_{c} or a real temperature Ta corrected by means of the transmittance Tr. Accordingly, the controller 11 can control the heater 7 using the real temperature Ta. Therefore, the controller 11 can control the heater 7 so that the temperature of the wafer W becomes, for example, 1000° C. with respect to the set temperature 1000° C. Alternatively, the controller 11 may calculate a real temperature Ta corrected by means of the transmittance Tr and uses the corrected real temperature Ta to control the heater 7. As described above, the film forming apparatus 1 according to the present embodiment can accurately control the temperature of the wafer W even if the transmittance Tr of the light transmission window 2a reduces. As a result, it is achieved to longer the cycle of maintenance such as replacement of the light transmission window 2a to improve productivity.

Subsequently, the operation of the film forming apparatus 1 according to the present embodiment will be explained.

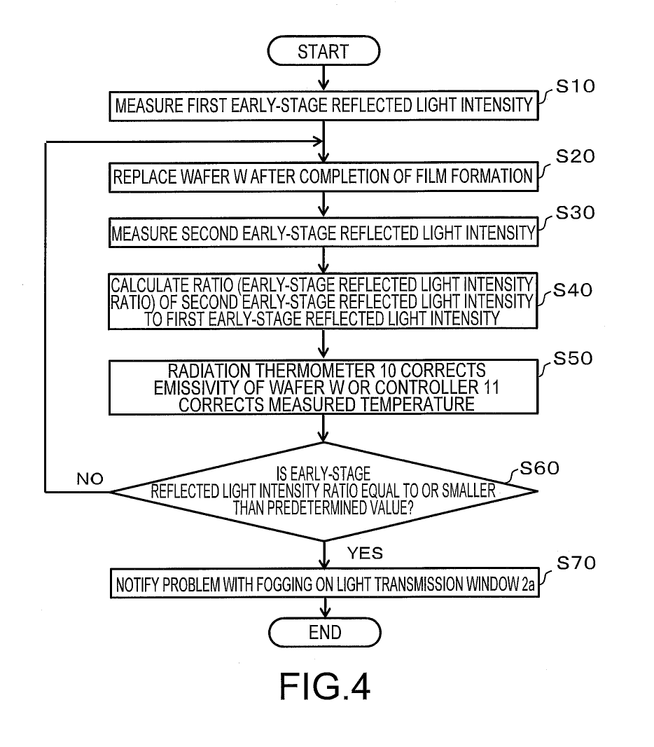

FIG. 4 is a flowchart showing an example of the operation of the film forming apparatus 1 according to the present embodiment. First of all, the optical monitor 12 measures a first early-stage reflected light intensity Ir1 before an initial film forming process as a first film forming process (S10). The initial film forming process is, for example, a first-time film forming process of the wafer W after replacement of the light transmission window 2a. The optical monitor 12 outputs the measured first early-stage reflected light intensity Ir1 to the radiation thermometer 10. The radiation thermometer 10 stores the first early-stage reflected light intensity Ir1 in an internal memory (not shown). It is a precondition in the initial film forming process that no fogging occurs on the light transmission window 2a, so that the transmittance Tr of the light transmission window 2a is 1 (Ir1/Ir1=1). Therefore, the radiation thermometer 10 outputs an emissivity ε and an apparent temperature T practically with no correction. Then, the controller 11 controls the heater 7 based on a measured temperature from the radiation thermometer 10.

After completion of the initial film forming process, the film forming apparatus 1 transfers a wafer W out of the chamber 2, which has been subjected to the film forming process and then transfers a second wafer W into the chamber 2, which is to be subsequently subjected to the film forming process (S20). The optical monitor 12 measures a second early-stage reflected light intensity Ir2 before a second-time film forming process (S30). The optical monitor 12 outputs the second early-stage reflected light intensity Ir2 measured before the second-time film forming process to the radiation thermometer 10. The radiation thermometer 10 stores the second early-stage reflected light intensity Ir2 in the internal memory.

Moreover, before a film forming process, the radiation thermometer 10 calculates a ratio (early-stage reflected light intensity ratio=Ir2/Ir1) of the second early-stage reflected light intensity Ir2 to the first early-stage reflected light intensity Ir1 (S40).

Subsequently, as described above, the radiation thermometer 10 calculates a transmittance Tr of the light transmission window 2a from the early-stage reflected light intensity ratio and multiplies the emissivity E of the wafer W by the transmittance Tr to correct the emissivity E of the wafer W (S50). For example, the transmittance Tr is the square root of the early-stage reflected light intensity ratio (Ir2/Ir1)^{1/2}. Accordingly, the radiation thermometer 10 can calculate a corrected emissivity ε_{c} (ε_{c}=ε×Tr) using the method 1, to calculate the real temperature Ta of the wafer W.

Instead of above, the controller 11 can calculate the real temperature Ta of the wafer W from the transmittance Tr using the method 2.

When using the method 2, the optical monitor 12 may output the first and second early-stage reflected light intensities Ir1 and Ir2 to the controller 11. In this case, the controller 11 stores the first and second early-stage reflected light intensities Ir1 and Ir2 in an internal memory (not shown) and calculates an early-stage reflected light intensity ratio (S40). The controller 11 calculates a transmittance Tr from the early-stage reflected light intensity ratio and, using the transmittance Tr, corrects a measured temperature (apparent temperature) measured by the radiation thermometer 10 to a real temperature Ta (S50). The controller 11 controls the heater 7 based on the corrected real temperature Ta.

A third-time film forming process and the following film forming processes are also executed in the same manner as the second-time film forming process. An early-stage reflected light intensity measured before each of the third-time film forming process and the following film forming processes is also referred to as a second early-stage reflected light intensity Ir2 for convenience. After each film forming process, the film forming apparatus 1 transfers a wafer W out of the chamber 2, which has been subjected to the film forming process and then transfers a wafer W into the chamber 2, which is to be subsequently subjected to the film forming process (S20). The optical monitor 12 measures a second early-stage reflected light intensity Ir2 before each film forming process (S30). The optical monitor 12 outputs the second early-stage reflected light intensity Ir2 measured before each film forming process to the radiation thermometer 10. The radiation thermometer 10 also stores, in the internal memory, the second early-stage reflected light intensity Ir2 before each of the third-time film forming process and the following film forming processes.

Subsequently, before each film forming process, the radiation thermometer 10 calculates a ratio (early-stage reflected light intensity ratio=Ir2/Ir1) of the second early-stage reflected light intensity Ir2 to the first early-stage reflected light intensity Ir1 (S40).

Subsequently, the radiation thermometer 10 calculates a transmittance Tr of the light transmission window 2a from the early-stage reflected light intensity ratio and multiplies the emissivity E of the wafer W by the transmittance Tr to correct the emissivity E of the wafer W (S50). Accordingly, the radiation thermometer 10 calculates the corrected emissivity ε_{c} (ε_{c}=ε×Tr) using the method 1, to calculate the real temperature Ta of the wafer W, or using the method 2, calculates the real temperature Ta of the wafer W from the transmittance Tr (S50). The controller 11 controls the heater 7 based on the calculated real temperature Ta.

Based on the early-stage reflected light intensity ratio, the controller 11 may notify a user of a problem with fogging on the light transmission window 2a. For example, the controller 11 determines whether the early-stage reflected light intensity ratio becomes equal to or smaller than a predetermined value (S60). If the number of times of film formation is small and the early-stage reflected light intensity ratio is larger than the predetermined value (NO in S60), the film forming apparatus 1 performs again the steps of S20 to S50 after the completion of film formation. On the contrary, if the early-stage reflected light intensity ratio becomes equal to or smaller than the predetermined value (YES in S60), the film forming apparatus 1 notifies the user of a problem with fogging on the light transmission window 2a (S70). The notification to the user may be an output to a monitor not shown or may be a warning sound given off by a speaker not shown.

As described above, the film forming apparatus 1 according to the present embodiment performs emissivity correction or measured temperature correction by measuring the early-stage reflected light intensity of the wafer W and calculating the early-stage reflected light intensity ratio. In this way, the film forming apparatus 1 can measure an accurate temperature of the wafer W even if fogging occurs on the light transmission window 2a.

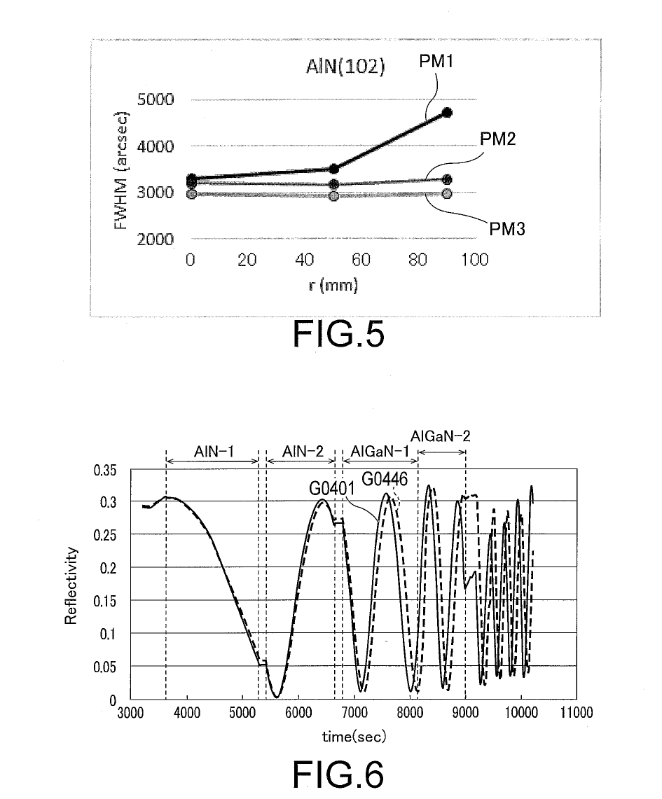

FIG. 5 is a figure showing measured values of a half width of diffraction intensity peak on an AIN (102) plane with the X-ray rocking curve. Data shown in FIG. 5 are measured data on a sample subjected to film formation in a run that corresponds to the 82-th run in run numbers (number of times of process) also used in FIG. 3. The abscissa indicates the distance from the center of the wafer W and the ordinate indicates the half width. The diffraction-peak half width in the X-ray rocking curve is used for crystallinity evaluation. The half width becomes wider, for example, as the crystallinity becomes worse due to crystal lattice distortion, crystal defects, etc.

FIG. 5 shows that, in the chamber PM1, crystallinity is degraded from the center area of the wafer W toward the outer peripheral area. The reason is as follows. The measured value L of the thermal radiation intensity reduces due to fogging on the light transmission window 2a, so that the radiation thermometer 10 outputs an apparent temperature T that is lower than a real temperature Ta of the wafer W. Accordingly, the controller 11 controls a process temperature to be higher than a desired temperature. As a result, the crystallinity of a thin film formed on the wafer W is degraded. In the chamber PM1, the crystallinity of the wafer W is degraded because of the process temperature controlled to be higher in the outer peripheral area of the wafer W.

In contrast, the film forming apparatus 1 according to the present embodiment accurately measures the real temperature Ta of the wafer W to control the process temperature of the wafer W based on the measured temperature. In this way, the film forming apparatus 1 can form a high-quality thin film while restricting the degradation of crystallinity that depends on the temperature.

As described above, the film forming apparatus 1 according to the present embodiment can calculate the transmittance Tr of the light transmission window 2a based on the early-stage reflected light intensity of the wafer W to correct the emissivity E or the measured temperature T even if fogging occurs on the light transmission window 2a. Accordingly, the film forming apparatus 1 can form a film having a desired film thickness or film quality. It is therefore achieved to decrease the frequency of maintenance of the light transmission window 2a and to improve the throughput of the film forming process and the productivity of semiconductor devices.

The reason for measuring the first early-stage reflected light intensity of the light transmission window 2a whenever the light transmission window 2a is replaced is to remove the influence of window-member individual differences. The window member used for the light transmission window 2a is an accurately processed optical component. However, due to errors in processed dimensions, surface finish, installation operation, etc., it is difficult to achieve a desired transmittance, no matter how often the window member is replaced, to the extent that no errors occur in temperature measurements when the window member is replaced. On the contrary, the above errors do not occur after the window member is replaced. Therefore, the influence of fogging on the light transmission window 2a can be accurately examined by evaluating the early-stage reflected light intensity, with the first early-stage reflected light intensity as a reference, which is measured just after the replacement of the window member. If the window-member replacement and installation can be repeated to the extent that the above errors can be ignored, it is not required to measure the first early-stage reflected light intensity just after the replacement of the window member.

It is rare but can be happened that the transmittance of an optical component increases due to adherence of deposits on the surface of the optical component. This is because of the decrease in reflectivity on the surface of the optical component due to the influence of the deposits. In this case, although the transmittance Tr becomes larger than 1, the temperature correction described so far can be performed in the same manner as described.

The change in emissivity E is not considered in the expression 2. The emissivity of a substance varies with temperature or varies depending on an optical interference effect of a thin film of a substance, which is different from the above-described substance, formed on the above-described substance. Even in this case, the relationship between the reflectivity and emissivity in the expression 1 holds. Therefore, the emissivity of the wafer W can be measured by measuring the reflectivity of the wafer W at a given temperature or even in the case where the optical interference effect occurs due to film formation. With the expression 2 having the emissivity measured in this way, the temperature can be correctly evaluated even in the case where there is a temperature change or a thin film is formed on the wafer W. Such a method of correcting the emissivity change while measuring the reflectivity during temperature change or film forming process is known as emissivity correcting pyrometry (ECP). By combining the ECP and the method of measuring the early-stage reflected light intensity in the present embodiment, the temperature during thin-film formation can be evaluated more correctly than calculation with a precondition of a constant emissivity.

In the case of a regular radiation thermometer with no measurements of a measurement target reflectivity, an interference effect due to thin-film formation on the wafer W may be reduced by adjusting the optical characteristics of the radiation thermometer. The adjusting method is to adjust the wavelength range of thermal radiation light to be measured by the radiation thermometer, preferably, within 5% or higher to the median value of the wavelength range. For example, when the median value of wavelength of thermal radiation light to be measured by the radiation thermometer is 1 μm, the measurement wavelength range is set to 975 nm or more but 1025 nm or less, more preferably, 10% or more of, and most preferably, 20% or more of the center wavelength in the measurement wavelength range. By setting the measurement wavelength range in this way, an interference effect can be decreased in formation of a thin film having a film thickness larger than about the median value of the measurement wavelength, which makes it possible for the regular radiation thermometer to perform temperature measurements at high accuracy.

### Second Embodiment

The film forming apparatus 1 according to the first embodiment measures the early-stage reflected light intensity of the wafer W to correct the emissivity or the measured temperature. In contrast, the film forming apparatus 1 according to the second embodiment measures a growth rate, as a parameter, of a film formed on the wafer W to correct the measured temperature. The growth rate is acquired by dividing the thickness of a formed film by a thin-film forming time, expressed in unit of thickness divided by time, such as, nanometer/minute and micron/hour. The growth rate is correlated with the temperature of the wafer W or a film forming temperature that is the temperature of the wafer W. The correlation is given due to the influence of film forming temperature on a film forming mechanism. Listed as a specific elementary process in the film forming mechanism, which is influenced by the film forming temperature, are thermal decomposition of a base material in a gas phase and thermal desorption of a base material adhered to a wafer, for example.

In a thin-film forming process such as MOCVD using a thermally-decomposable base material, if the film forming temperature is low, the base material does not decompose, so that a thin film does not grow. As the film forming temperature reaches a certain degree of temperature or higher, the base material starts decomposition, so that the deposition rate increases as the temperature increases. As the film forming temperature further becomes higher, the thermal decomposition of a base material in a gas phase becomes remarkable, so that the base material cannot reach the wafer.

In the above case, the deposition rate reduces as the film forming temperature increases. The base material adhered to the surface on which a thin film is to be formed is desorbed again in the gas atmosphere when the film forming temperature is high, which reduces a practical growth rate. It is general to raise the film forming temperature to form a thin film of excellent quality. In such a temperature range, generally, as the film forming temperature increases, the film forming rate decreases. The film forming apparatus 1 uses such a correlation between the film forming temperature and the growth rate to measure the growth rate to measure an accurate temperature of the wafer W.

The film forming apparatus 1 uses a reflected light intensity measured by the optical monitor 12 to measure a growth rate. The film forming apparatus 1 according to the second embodiment has the same configuration as the film forming apparatus 1 according to the first embodiment, and hence the detailed explanation of the configuration is omitted.

The growth rate can be detected in situ by monitoring the change in light reflectivity with time. In this method, light is emitted to a substrate through an optical window provided on the wall of a film forming apparatus to measure a reflectivity of light having a certain predetermined wavelength during a film forming process. In the case where the substrate surface is like a mirror surface, when light is emitted to a thin film formed on the substrate, the measured reflectivity periodically varies with respect to the thin-film thickness due to an interference effect of reflected light on the thin-film surface and reflected light on the interface between the substrate and the thin film. In other words, the reflectivity is a periodic function of the thin-film thickness. Accordingly, an optical constant, a film thickness, etc. of a formed thin film can be calculated from the cycle of change in reflectivity with respect to the thin-film thickness, and from reflectivity minimum and maximum values, etc. The growth rate can be calculated from a thin-film forming time.

FIG. 6 is a figure showing measured values of reflectivity varied with time during AlN- and AlGaN-film formation. The ordinate indicates reflectivity and the abscissa indicates time. Signs G0401 and G0446 are a process number of the film forming process. For example, the film forming apparatus 1 performs a process G0401, and thereafter, repeats the film forming process by 44 times, and then performs a process G0446. The film forming apparatus 1 according to the second embodiment can be used for formation of several types of films on the wafer W. However, hereinbelow, formation of, for example, an AlN-, GaN-, AlGaN- or InGaN-film on a silicon wafer W will be explained.

Now referring to FIG. 6, the cycle of change in reflectivity of the wafer W with time in the process G0446 is longer than the cycle of change in reflectivity of the wafer W with time in the process G0401. As described above, since the reflectivity is a periodic function of the thin-film thickness, a longer cycle means reduction in thin-film growth rate. For example, the reflectivities in the processes G0401 and G0446 vary in almost at the same cycle in film formation of thin films AlN-1 and AlN-2. In other words, in the processes G0401 and G0446, the thin films AlN-1 and AlN-2 grow at almost the same rate. In contrast, in film formation of thin films AlGaN-1 and AlGaN-2, the change in reflectivity in the process G0446 is delayed more than the change in reflectivity in the process G0401. In other words, in the film formation of the thin films AlGaN-1 and AlGaN-2, the growth rate in the process G0446 is reduced more than that in the process G0401. As described above, it is indicated that the growth rate in the process G0446 is slower than the growth rate in the process G0401 and the film forming temperature in the process G0446 is higher than the film forming temperature in the process G0401.

The optical monitor 12 outputs the reflectivity change with time to the controller 11. The controller 11 uses the reflectivity change with time to measure the growth rate.

Hereinafter, a method of calculating the optical constant and growth rate of a film to be formed, from the reflectivity dependency on film thickness, will be explained.

In the case where light is vertically incident on a substrate, when an electric-field reflectivity in air (refractive index=1) and on the surface of a thin film (refractive index=n, absorption coefficient=0) formed on the substrate is denoted as r₀, the reflectivity r₀ is expressed by the following expression 8. Hereinafter, in the present embodiment, the term “air” may be replaced with “vacuum” or “gas”.

r₀=(1−n)/(1+n) (expression 8)

In the case where a thin film absorbs light, in the expression 8, the refractive index n is replaced with a complex refractive index=n+ik (k being an absorption coefficient), where a sign “i” is in the unit of imaginary number (the same, hereinafter).

A reflectivity r₁ on the interface between the thin film and the substrate is expressed by the following expression 9 using a substrate absorption coefficient kₛ and a substrate refractive index nₛ.

r₁=(n−ikₛ−nₛ)/(n+ikₛ+nₛ) (expression 9)

Actual reflected light from a thin film is an addition of reflected light on the interface between air and the thin film, and every light that reciprocates between the interface between the thin film and the substrate, and the interface between the thin film and the air by p times (p being an integer of 1 or larger), after passing through the interface between the air and the thin film, and then passes through the interface between the thin film and the air. Phase changes when light passes through the thin film, so that, when the phase change is considered, an electric field Eᵣ of reflected light is expressed by the following expression 10.

Eᵣ=E₀r₀+E₀(1−r₀²)r₁·exp(i2ϕ){1−r₁r₀·exp(i2ϕ)+(−r₁r₀)2exp(i4ϕ)+ . . . }−=E₀r₀+E₀(1−r₀²)r1·exp(i2ϕ)/{1+r₁r₀·exp(i2ϕ)}=E₀{r₀+r₁·exp(i2ϕ)}/{1+r₁r₀·exp(i2ϕ)} (expression 10)

A sign E₀ in the expression 10 denotes an electric field of light emitted to the thin film. Therefore, an electric-field reflectivity r of the thin film is expressed by the following expression 11.

r=Eᵣ/E₀={r₀+r₁·exp(i2ϕ)}/{1+r₁r₀·exp(i2ϕ)} (expression 11)

A phase difference (hereinafter, referred to as a phase) ϕ, which is generated when light reciprocates inside the thin film one time, is expressed by the following expression 12 using a refractive index n of the thin film, a film thickness d of the thin film, and a wavelength A of the light.

ϕ=2πnd/λ(expression 12)

As the expression 12 indicates, the phase ϕ is proportional to the film thickness d and linearly increases as the film thickness d increases. An observed light reflectivity (energy reflectivity) is proportional to the square root of the amplitude of an electric-filed reflectivity. In other words, the electric-filed reflectivity and the energy reflectivity are periodic functions of the film thickness. Conversely, if it is supposed that the thin-film thickness is proportional to the growth time, the factors n, nₛ and kₛ, and a growth rate (d/time), which are used in the expression 11 through the expressions 8 and 9, can be acquired from the reflectivity change in time.

Using such a method described above, the controller 11 can measure the growth rate, from the reflectivity change in time.

Instead of the above growth-rate calculation method, the controller 11 may measure the growth rate using the duration of 1 wavelength from a given peak to the next peak in the reflectivity change with time. In this case, although the growth rate accuracy is reduced more than the above method, the controller 11 can measure the growth rate more easily.

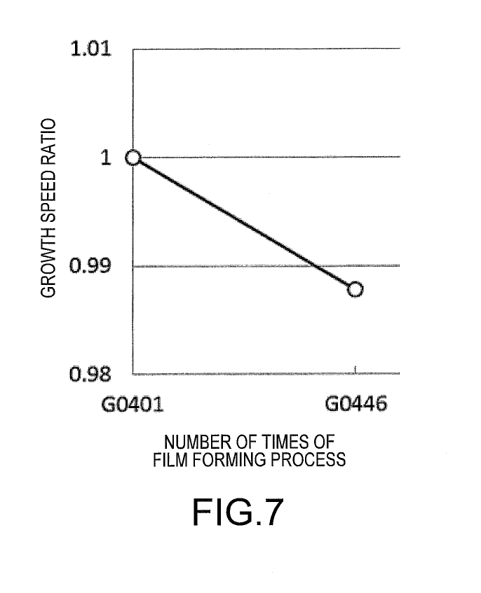

FIG. 7 is a figure showing the measured values of a GaN growth rate ratio to the number of times of film forming process. The abscissa indicates the number of times of film forming process (process number) and the ordinate indicates the growth rate ratio.

The growth rate ratio is a ratio (Gr2/Gr1) of a first growth rate Gr1 measured through a new (just replaced) light transmission window 2a in a given film forming process (first film forming process) and a second growth rate Gr2 measured through the light transmission window 2a in a second film forming process after the first film forming process. In the initial film forming process, the growth rate ratio is a ratio (Gr1/Gr1=1) of the first growth rate Gr1 and the first growth rate Gr1. In the example shown in FIG. 7, the process G0401 is the initial film forming process with the growth rate ratio of 1.

The first growth rate Gr1 is a growth rate measured in the execution of the first-time film forming process. In other words, the first growth rate Gr1 is a growth rate calculated using a reflected light intensity measured in the execution of the first-time film forming process of the wafer W. The second growth rate Gr2 is a growth rate calculated using a reflected light intensity measured in the execution of a film forming process that is the second-time film forming process or any film forming process after the second-time film forming process. In other words, the second growth rate Gr2 is a growth rate measured in the execution of a film forming process of the wafer W, which is the second-time film forming process or any film forming process after the second-time film forming process.

The first growth rate Gr1 may be measured in a film forming process after the execution of several times of film forming process, if there is no fogging on the light transmission window 2a. In this case, the second growth rate Gr2 is measured in any film forming process after the first growth rate Gr1 is measured. Moreover, the first and second growth rates Gr1 and Gr2 may be measured for all of the thin films AlN-1, AlN-2, AlGaN-1, and AlGaN-2, or for any of them. Nevertheless, the thin film to be subjected to the comparison of growth rate ratio is preferably one and the same thin film.

In the initial film forming process G0401, the growth rate ratio is a ratio (Gr1/Gr1=1) of the first growth rate Gr1 and the first growth rate Gr1. When the number of times of film forming process is 1 or larger, the growth rate ratio (Gr2/Gr1) tends to reduce as the number of times of film forming process increases. For example, in the process G0446, the growth rate ratio (Gr2/Gr1) is 0. 99 or smaller. This is because, in the process G0446, fogging occurs on the light transmission window 2a to raise the GaN-film forming temperature. The controller 11 uses the above growth rate ratio to correct the film forming temperature.

For example, as shown in FIG. 7, the growth rate ratio in G0446 is about 99% (about 0.99) which is decreased from that in G0401 by about 1%. In the example of the present embodiment, it has been empirically found that the real temperature is in the range from about 1002° C. to 1003° C. in the case where the growth rate ratio is decreased by about 1% at the apparent temperature of 1000° C. The growth rate dependency on temperature is practically depends on the film forming conditions, the film forming apparatus, etc. It is therefore required to acquire data of the growth rate dependency on temperature in advance for actual film formation. The controller 11 stores an empirical correlation between the growth rate and film forming temperature as a relational expression. Accordingly, the controller 11 calculates a temperature error from the decrease in growth rate ratio and uses the temperature error to correct a measured temperature (apparent temperature T) acquired from the radiation thermometer 10 to an accurate film-forming temperature (real temperature Ta). In this way, the controller 11 can control the heater 7 using an accurate real temperature Ta.

Subsequently, an operation of the film forming apparatus 1 according to the second embodiment will be explained.

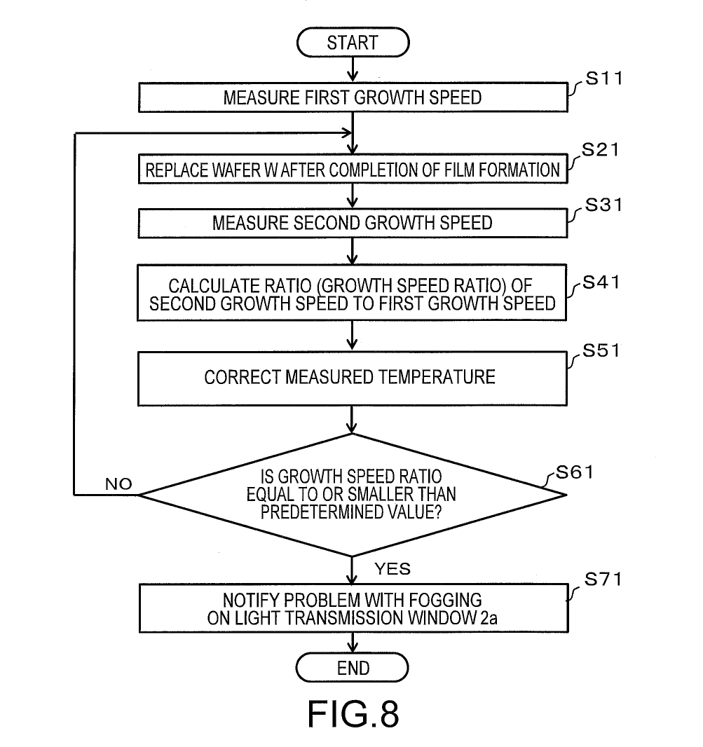

FIG. 8 is a flowchart showing an operation of the film forming apparatus 1 according to the second embodiment. First of all, the optical monitor 12 measures a reflectivity change with time in an initial film forming process as a first film forming process. The initial film forming process is, for example, a first-time film forming process of the wafer W after the replacement of the light transmission window 2a.

The optical monitor 12 outputs the measured reflectivity change with time to the controller 11. The controller 11 calculates a first growth rate Gr1 in the initial film forming process (S11). The controller 11 stores the first growth rate Gr1 in an internal memory (not shown). It is a precondition in the initial film forming process that no fogging occurs on the light transmission window 2a, so that the transmittance Tr of the light transmission window 2a is 1. Therefore, the controller 11 outputs an apparent temperature T from the radiation thermometer 10 practically with no correction.

After the completion of the initial film forming process, the film forming apparatus 1 transfers a wafer W out of the chamber 2, which has been subjected to the film forming process and then transfers a second wafer W into the chamber 2, which is to be subsequently subjected to the film forming process (S21). Subsequently, the optical monitor 12 measures a thin-film reflectivity change with time in a second-time film forming process. The controller 11 calculates a second growth rate Gr2 in the second-time film forming process (S31). Subsequently, the controller 11 calculates a growth rate ratio (Gr2/Gr1) (S41). Moreover, the controller 11 calculates a film-forming temperature error from the growth rate ratio to correct the apparent temperature T from the radiation thermometer 10 to a real temperature Ta (S51). The controller 11 controls the heater 7 based on the corrected real temperature Ta.

A third-time film forming process and the following film forming processes are also executed in the same manner as the second-time film forming process. A growth rate measured in each of the third-time film forming process and the following film forming processes is also referred to as a second growth rate Gr2 for convenience. After each film forming process, the film forming apparatus 1 transfers a wafer W out of the chamber 2, which has been subjected to the film forming process and then transfers a wafer W into the chamber 2, which is to be subsequently subjected to the film forming process (S21). The optical monitor 12 measures a second growth rate Gr2 in each film forming process (S31). The optical monitor 12 outputs the second growth rate Gr2 measured in each film forming process to the controller 11. The controller 11 also stores, in the internal memory, the second growth rate Gr2 in each of the third-time film forming process and the following film forming processes. Subsequently, the radiation thermometer 10 calculates a ratio (growth rate ratio=Gr2/Gr1) of the second growth rate Gr2 to the first growth rate Gr1 (S41). The controller 11 calculates a film-forming temperature error from the growth rate ratio to correct the apparent temperature T from the radiation thermometer 10 to the real temperature Ta (S51). The controller 11 controls the heater 7 based on the corrected real temperature Ta.

Based on the growth rate ratio, the controller 11 may notify a user of a problem with fogging on the light transmission window 2a. For example, the controller 11 determines whether the growth rate ratio becomes equal to or smaller than a predetermined value (S61). If the number of times of film formation is small and the growth rate ratio is larger than the predetermined value (NO in S61), the film forming apparatus 1 performs again the steps of S21 to S51 after the completion of film formation. On the contrary, if the growth rate ratio becomes equal to or smaller than the predetermined value (YES in S61), the film forming apparatus 1 notifies the user of a problem with fogging on the light transmission window 2a (S71). The notification to the user may be an output to a monitor not shown or may be a warning sound given off by a speaker not shown.

As described above, the film forming apparatus 1 according to the second embodiment measures the thin-film growth rate and calculates the growth rate ratio to correct the measured temperature from the radiation thermometer 10. In this way, the film forming apparatus 1 according to the second embodiment achieves the same effect as the film forming apparatus 1 according to the first embodiment.

The example shown in the present embodiment includes the step S11 to measure the first growth rate after the replacement of the light transmission window. However, the step S11 may be omitted in the case where a growth rate to become a reference is measured in advance. This is because, in the case where the temperature does not give a large influence on the thin-film refractive index, fogging on the light transmission window does not give a large influence on the growth rate accuracy. Specifically, the conditions for the film forming temperature not to give a large influence on the refractive index of a material to be subjected to film formation are that the material is one element or a stoichiometric ratio does not largely depend on the growth rate and that the characteristics such as impurity concentration, which influences the refractive index, do not largely depend on the temperature. Specific cases where the step S11 can be omitted are such that film formation is carried out at a sufficiently high temperature with a one-element material such as silicon or germanium, or a two-element material such as gallium nitride (GaN) or aluminum nitride (AlN).

In the same manner as the first embodiment, in the second embodiment, with the ECP or the adjustments to the optical characteristics of the radiation thermometer, an interference effect due to thin-film formation can be reduced in temperature measurements.

### Third Embodiment

The film forming apparatus 1 according to the second embodiment measures the growth rate of crystal of a thin film during film formation to the wafer W to correct the measured temperature. In contrast, the film forming apparatus 1 according to the third embodiment measures the refractive index of a thin film during film formation to the wafer W to correct the measured temperature. The refractive index of the thin film has a correlation with the temperature or film forming temperature of the wafer W.

For example, in a mixed crystal compound such as InGaN and AlGaN, the composition ratio of the mixed crystal varies depending on the film forming temperature and the refractive index varies accordingly.

The film forming apparatus 1 uses a reflected light intensity measured by the optical monitor 12 to measure a refractive index of a thin film. The film forming apparatus 1 according to the third embodiment has the same configuration as the film forming apparatus 1 according to the first embodiment, and hence the detailed explanation of the configuration is omitted.

For the refractive index of a thin film, the refractive index n calculated in the second embodiment can be used. In the same manner as the deposition rate, the refractive index n of the thin film has a correlation with the film forming temperature and hence is expressed in an empirical relational expression. The controller 11 stores such a relational expression between the refractive index n and the film forming temperature. The controller 11 acquires a refractive index ratio instead of the growth rate ratio in the second embodiment and calculates a temperature error from the change in refractive index ratio. The controller 11 uses the temperature error to correct a measured temperature (apparent temperature T) acquired from the radiation thermometer 10 to an accurate film forming temperature (real temperature Ta). Accordingly, the controller 11 can control the heater 7 using the accurate real temperature Ta.

In the same manner as the first embodiment, in the second embodiment, with the ECP or the adjustments to the optical characteristics of the radiation thermometer, an interference effect due to thin-film formation can be reduced in temperature measurements.

The first to third embodiments can be combined freely. In this case, for the corrected measured temperature for use in control of the heater 7, the measured temperature acquired in any of the first to third embodiments may be used at first priority or the average value of the measured temperatures acquired in the first to third embodiments may be used.

An example explained in the first to third embodiments is a growing apparatus such as shown in FIG. 1 for processing one wafer W. However, not only limited to that, the embodiments are applicable to an apparatus for processing a large number of wafers W all at once.

The method explained in the present embodiment is to use a parameter as it is, which has a correlation with the temperature measured in each growth, for temperature control in each growth. However, for the parameter having a correlation with the temperature, parameters, which are measured in several different growth processes and then subjected to statistical processing, may be used. In other words, in the case where the above-mentioned parameter having a correlation with the temperature has a measurement error and hence temperature control becomes unstable when the parameter having a correlation with the temperature measured in each growth is used for temperature control as it is, for example, by taking the average value of parameters, each discussed above, measured in processes from a given growth to prior several runs, the influence of an error in each run can be mitigated. Or a standard value is set for a parameter having a correlation with the temperature and, if the value of parameter having a correlation with the temperature exceeds the standard value, the parameter can be reflected in the temperature control. For example, in the case where fogging on the light transmission window 2a gradually proceeds as the growth continues, the following process can be performed: if a temperature error calculated based on a parameter having a correlation with the temperature is smaller than the set standard value, the parameter is not reflected in the temperature control and a predetermined correction value acquired in advance is used for the temperature control, at a growth run in which the temperature error becomes equal to or larger than the standard value, and thereafter. If the temperature error becomes again smaller than the standard value thereafter, the predetermined correction value is continuously used for the temperature control.

For the above statistical processing, a well-known method can be used as required in accordance with how to form a film.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A film forming apparatus comprising:
a film forming chamber accommodating a substrate and performing a film forming process per the substrate;
a gas supplier supplying a gas onto the substrate;
a heater heating the substrate;
a window provided to the film forming chamber;
a radiation thermometer measuring a temperature of the substrate through the window;
a parameter acquirer acquiring a parameter correlated with the temperature of the substrate;
a corrector correcting the temperature of the substrate based on a change from an initial value of the parameter; and
a controller controlling the heater based on the temperature of the substrate or corrected temperature of the substrate.

2. The apparatus according to claim 1, wherein the corrector corrects the temperature of the substrate in view of change in emissivity due to temperature or due to an optical interference effect caused by a formed thin film.

3. The apparatus according to claim 1, wherein the corrector corrects the temperature of the substrate based on a first reflected light intensity acquired as the parameter before a first film forming process and a second reflected light intensity acquired as the parameter before a second film forming process after the first film forming process.

4. The apparatus according to claim 3 further comprising an environment thermometer measuring an environment temperature of the film forming chamber,
wherein the corrector corrects the temperature of the substrate based on the first reflected light intensity and the second reflected light intensity measured in a substantially same environment temperature.

5. The apparatus according to claim 3, wherein the corrector corrects the temperature of the substrate based on a ratio of the first reflected light intensity and the second reflected light intensity.

6. The apparatus according to claim 3, wherein the corrector corrects an emissivity based on a ratio of the first reflected light intensity and the second reflected light intensity to calculate a corrected emissivity, and uses a thermal radiation light intensity and the corrected emissivity to calculate the temperature of the substrate.

7. The apparatus according to claim 1, wherein the corrector corrects the temperature of the substrate based on a growth rate of a predetermined film formed on the substrate, the growth rate being acquired as the parameter.

8. The apparatus according to claim 1, wherein the corrector corrects the temperature of the substrate based on a refractivity of a predetermined film formed on the substrate, the refractivity being acquired as the parameter.

9. A film forming method to supply a gas onto a substrate while heating the substrate accommodated in a film forming chamber to a predetermined temperature, comprising:
measuring a temperature of the substrate through a window provided to the film forming chamber;
acquiring a parameter correlated with the temperature of the substrate;
correcting the temperature of the substrate based on a change from an initial value of the parameter; and
controlling the heater so that corrected temperature of the substrate becomes the predetermined temperature.

10. The method according to claim 9, wherein the temperature of the substrate is corrected in view of change in emissivity due to temperature or due to an optical interference effect caused by a formed thin film.

11. The method according to claim 9 further comprising, in the correction of the temperature of the substrate, correcting the temperature of the substrate based on a first reflected light intensity acquired as the parameter before a first film forming process and a second reflected light intensity acquired as the parameter before a second film forming process after the first film forming process.

12. The method according to claim 11, wherein the temperature of the substrate is corrected based on the first reflected light intensity and the second reflected light intensity measured in a substantially same environment temperature.

13. The method according to claim 11, wherein the temperature of the substrate is corrected based on a ratio of the first reflected light intensity and the second reflected light intensity.

14. The method according to claim 11, further comprising, in the correction of the temperature of the substrate:
correcting an emissivity based on the ratio of the first reflected light intensity and the second reflected light intensity to calculate a corrected emissivity and;
calculating the temperature of the substrate using a thermal radiation light intensity and the corrected emissivity.

15. The method according to claim 9, further comprising, in the correction of the temperature of the substrate, correcting the temperature of the substrate based on a growth rate of a predetermined film formed on the substrate, the growth rate being acquired as the parameter.

16. The method according to claim 9, further comprising, in the correction of the temperature of the substrate, correcting the temperature of the substrate based on a refractivity of a predetermined film formed on the substrate, the refractivity being acquired as the parameter.
